(19) United States
(12) Patent Application Publication
(10) Pub. No.: US 2021/0360753 A1
(43) Pub. Date: Nov. 18, 2021

(54) DUAL-CHAMBER DEFROSTING APPARATUS WITH IMPEDANCE MATCHING NETWORK AND METHODS OF OPERATION THEREOF

(71) Applicant: NXP USA, Inc., AUSTIN, TX (US)

(72) Inventors: Qi Hua, Wu Xi (CN); Tonghe Liu, Pudong new district (CN); Changyang Wang, Shanghai (CN)

(21) Appl. No.: 17/065,592

(22) Filed: Oct. 8, 2020

(30) Foreign Application Priority Data
May 13, 2020 (CN) 202010402162.3

(51) Int. Cl. H05B 6/72; H01Q 1/02; H01Q 1/38

(52) U.S. Cl. CPC H05B 6/72; A23L 3/365; H01Q 1/38; H01Q 1/02

(57) ABSTRACT

A thermal increase system may include first and second cavities disposed on opposite sides of a first electrode. The first cavity may have a first height that is approximately equal to a second height of the second cavity. The first electrode may be disposed within a containment structure that is capacitively coupled to the first electrode. An upper wall of the containment structure may include a second electrode that is capacitively coupled to the first electrode. A bottom wall of the containment structure may include a third electrode that is capacitively coupled to the first electrode. The first electrode may receive the RF signal from an RF signal source, which may cause electric field magnitudes within the first and second cavities to increase, which may increase the temperature of loads disposed within the first and/or second cavities.

### CROSS-REFERENCE TO RELATED APPLICATION

This application claims the priority under 35 U.S.C. § 119 of China patent application no. 202010402162.3, filed May 13, 2020 the contents of which are incorporated by reference herein.

### TECHNICAL FIELD

Embodiments of the subject matter described herein relate generally to apparatus and methods of defrosting a load using radio frequency (RF) energy.

### BACKGROUND

Conventional capacitive food defrosting (or thawing) systems include large planar electrodes contained within a heating compartment. After a food load is placed between the electrodes, low power electromagnetic energy is supplied to at least one of the electrodes to provide gentle warming of the food load. As the food load thaws during the defrosting operation, the impedance of the food load changes. Accordingly, the power transfer to the food load also changes during the defrosting operation. A powered electrode of such a defrosting system should be secured a sufficient distance apart from an outer, grounded containment structure of the defrosting system to reduce electrical arcing risk between the electrode and the containment structure, and to ensure adequate defrosting efficiency of the system. In conventional defrosting systems, a first area on one side of the powered electrode may receive a food load, while a second area on the opposite side of the powered electrode is sealed off from the first area. This second, sealed off area is considered “headroom”, is dedicated to storing circuitry of the conventional defrosting system, and adds to the overall dimension of the defrosting system. What are needed are apparatus and methods for defrosting food loads (or other types of loads) that are more compact, while adequately improving parasitic capacitance and performing with adequate efficiency.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a perspective view of a defrosting appliance, in accordance with an example embodiment;

FIG. 2 is a perspective view of a refrigerator/freezer appliance that includes other example embodiments of defrosting systems;

FIG. 3 is a simplified block diagram of a defrosting apparatus, in accordance with an example embodiment;

FIG. 4A shows a cross-sectional side-view of a dual-chamber defrosting apparatus, in accordance with an example embodiment;

FIG. 4B shows an illustrative representation of electric field intensity within the dual-chamber defrosting apparatus of FIG. 4A during a heating operation, in accordance with an example embodiment;

FIG. 5A shows an example cross-sectional side view of a single-chamber defrosting apparatus;

FIG. 5B shows a representation of electric field intensity within the single-chamber defrosting apparatus of FIG. 5A during a heating operation; and

FIG. 6 is a flowchart of a method of operating a dual-chamber defrosting system with dynamic load matching, in accordance with an example embodiment.

### DETAILED DESCRIPTION

The following detailed description is merely illustrative in nature and is not intended to limit the embodiments of the subject matter or the application and uses of such embodiments. As used herein, the words “exemplary” and “example” mean “serving as an example, instance, or illustration.” Any implementation described herein as exemplary or an example is not necessarily to be construed as preferred or advantageous over other implementations. Furthermore, there is no intention to be bound by any expressed or implied theory presented in the preceding technical field, background, or the following detailed description.

Embodiments of the subject matter described herein relate to solid-state defrosting apparatus that may be incorporated into stand-alone appliances or into other systems. As described in greater detail below, exemplary defrosting systems are realized using a first electrode disposed in a cavity, an amplifier arrangement (including one or more transistors), an impedance matching network coupled between an output of the amplifier arrangement and the first electrode, and a measurement and control system that can detect when a defrosting operation has completed. In an embodiment, the impedance matching network is a variable impedance matching network that can be adjusted during the defrosting operation to improve matching between the amplifier arrangement and the cavity.

Generally, the term “defrosting” means to elevate the temperature of a frozen load (e.g., a food load or other type of load) to a temperature at which the load is no longer frozen (e.g., a temperature at or near 0 degrees Celsius). As used herein, the term “defrosting” more broadly means a process by which the thermal energy or temperature of a load (e.g., a food load or other type of load) is increased through provision of RF power to the load. Accordingly, in various embodiments, a “defrosting operation” may be performed on a load with any initial temperature (e.g., any initial temperature above or below 0 degrees Celsius), and the defrosting operation may be ceased at any final temperature that is higher than the initial temperature (e.g., including final temperatures that are above or below 0 degrees Celsius). That said, the “defrosting operations” and “defrosting systems” described herein alternatively may be referred to as “thermal increase operations” and “thermal increase systems.” The term “defrosting” should not be construed to limit application of the invention to methods or systems that are only capable of raising the temperature of a frozen load to a temperature at or near 0 degrees Celsius.

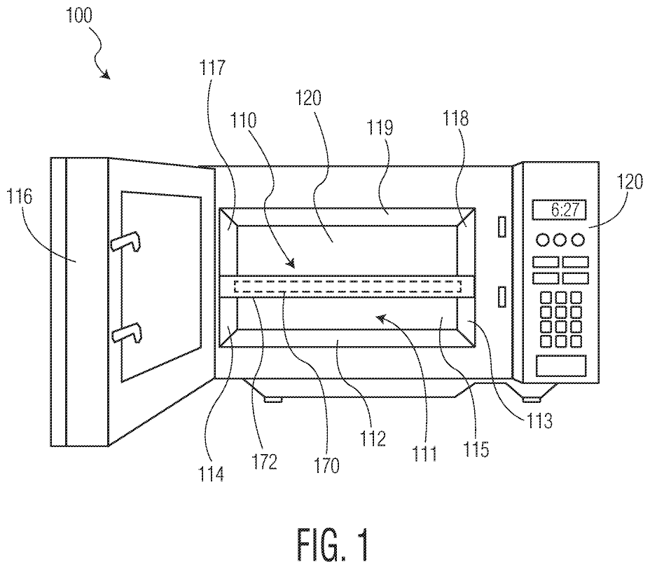

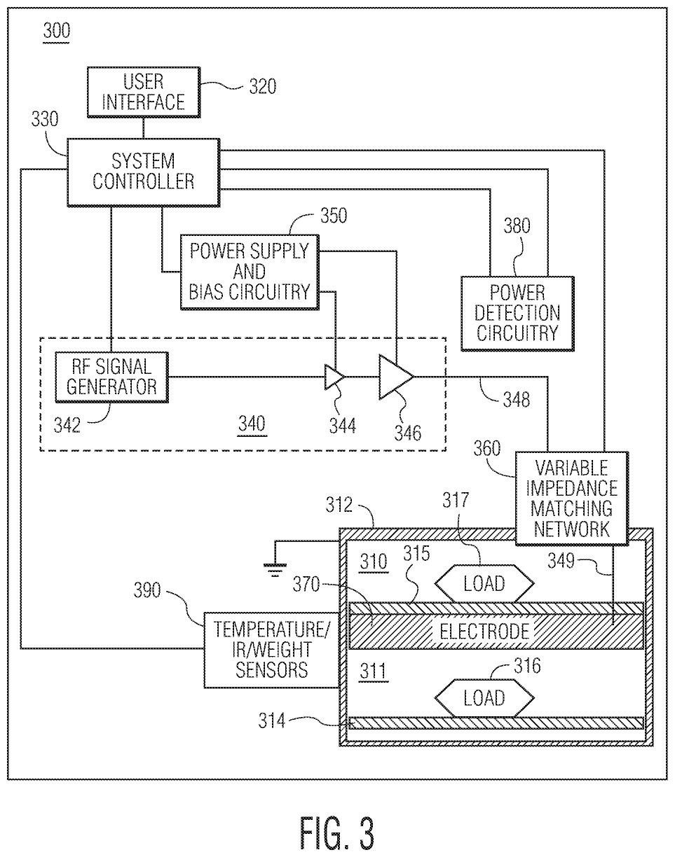

FIG. 1 is a perspective view of a defrosting system 100, in accordance with an example embodiment. Defrosting system 100 includes a first defrosting cavity 110, a second defrosting cavity 111, a control panel 120, one or more radio frequency (RF) signal sources (e.g., RF signal source 340, FIG. 3), a power supply (e.g., power supply 350, FIG. 3), a platform 172 that includes a first electrode 170 and that separates the first defrosting cavity from the second defrosting cavity, power detection circuitry (e.g., power detection circuitry 380, FIG. 3), and a system controller (e.g., system controller 330, FIG. 3).

The defrosting system 100 essentially includes an outer housing with a large interior chamber that is defined by cavity walls 112-115, 117-120 and an interior surface of door 116. The interior chamber includes the first and second defrosting cavities 110, 111. The first defrosting cavity 110 is defined by interior surfaces of side, top, and back cavity walls 117, 118, 119, 120, an upper surface of platform 172, and an interior surface of door 116. The second defrosting cavity 111 is defined by interior surfaces of bottom, side, and back cavity walls 112, 113 114, 115, a lower surface of platform 172, and an interior surface of door 116. According to an embodiment, walls 114 and 117 are co-planar with each other, walls 113, 118 are co-planar with each other, and walls 115, 120 are co-planar with each other. With door 116 closed, the defrosting cavity 110 defines a first enclosed air cavity and the defrosting cavity 111 defines a second enclosed air cavity. As used herein, the term “air cavity” may mean an enclosed area that contains air or other gasses (e.g., defrosting cavity 110, 111).

According to an embodiment, the first electrode 170 is included in the platform 172, the first electrode 170 is electrically isolated from the remaining cavity walls (e.g., walls 113, 114, 117, 118, and door 116), which may be electrically grounded. For example, the first electrode 170 may be embedded in non-electrically conductive (e.g., electrically insulative) material. As another example, the first electrode 170 may be interposed between a first section of non-electrically conductive material and a second section of non-electrically conductive material. The first non-electrically conductive material may form an upper surface of the platform 172 (e.g., which may be considered the floor of the defrosting cavity 110), and the second non-electrically conductive material may form a lower surface of the platform 172 (e.g., which may be considered the ceiling of the defrosting cavity 111). The system 100 may be simplistically modeled as two capacitors, where the first electrode 170 functions as one conductive plate of both capacitors, the grounded cavity walls (e.g., walls 112-115) function as a second conductive plate (or electrode) of a first capacitor, the grounded cavity walls (e.g., walls 117-120) function as a second conductive plate (or electrode) of a second capacitor, and the air cavities (including any loads contained therein) function as dielectric medium between the first and second conductive plates of each capacitor. Although not shown in FIG. 1, one or more non-electrically conductive barriers (e.g., barrier 314, 315, FIG. 3) also may be included in the system 100, and such non-conductive barriers may function to electrically and physically isolate a first load within cavity 111 from the bottom cavity wall 112 and/or to physically isolate a second load within cavity 110 from the upper surface of the platform 172.

According to an embodiment, during operation of the defrosting system 100, a user (not illustrated) may place one or more loads (e.g., food and/or liquids) into the defrosting cavity 110 and/or into the defrosting cavity 111, and optionally may provide inputs via the control panel 120 that specify characteristics of the load(s). For example, the specified characteristics may include an approximate weight of the load(s). In addition, the specified load characteristics may indicate the material(s) from which such load(s) is/are formed (e.g., meat, bread, liquid). In alternate embodiments, the load characteristics may be obtained in some other way, such as by scanning a barcode on the load packaging or receiving a radio frequency identification (RFID) signal from an RFID tag on or embedded within the load(s). Either way, as will be described in more detail later, information regarding such load characteristics enables the system controller (e.g., system controller 330, FIG. 3) to establish an initial state for the impedance matching network of the system at the beginning of the defrosting operation, where the initial state may be relatively close to an optimal state that enables maximum RF power transfer into the load(s). Alternatively, load characteristics may not be entered or received prior to commencement of a defrosting operation, and the system controller may establish a default initial state for the impedance matching network.

To begin the defrosting operation, the user may provide an input via the control panel 120. In response, the system controller causes the RF signal source(s) (e.g., RF signal source 340, FIG. 3) to supply an RF signal to the first electrode 170, which responsively radiates electromagnetic energy into the defrosting cavities 110, 111. The electromagnetic energy increases the thermal energy of the load(s) (i.e., the electromagnetic energy causes the load(s) to warm up).

During the defrosting operation, the impedance of the load(s) (and thus the total input impedance of each cavity 110, 111 plus load(s)) changes as the thermal energy of the load(s) increases. The impedance changes alter the absorption of RF energy into the load(s), and thus alter the magnitude of reflected power. According to an embodiment, power detection circuitry (e.g., power detection circuitry 380, FIG. 3) continuously or periodically measures the forward and reflected power along a transmission path (e.g., transmission path 348, FIG. 3) between the RF signal source (e.g., RF signal source 340, FIG. 3) and the first electrode 170. Based on these measurements, the system controller (e.g., system controller 330, FIG. 3) may detect completion of the defrosting operation, as will be described in detail below. According to a further embodiment, the impedance matching network is variable, and based on the forward and/or reflected power measurements, the system controller may alter the state of the impedance matching network during the defrosting operation to increase the absorption of RF power by the load(s).

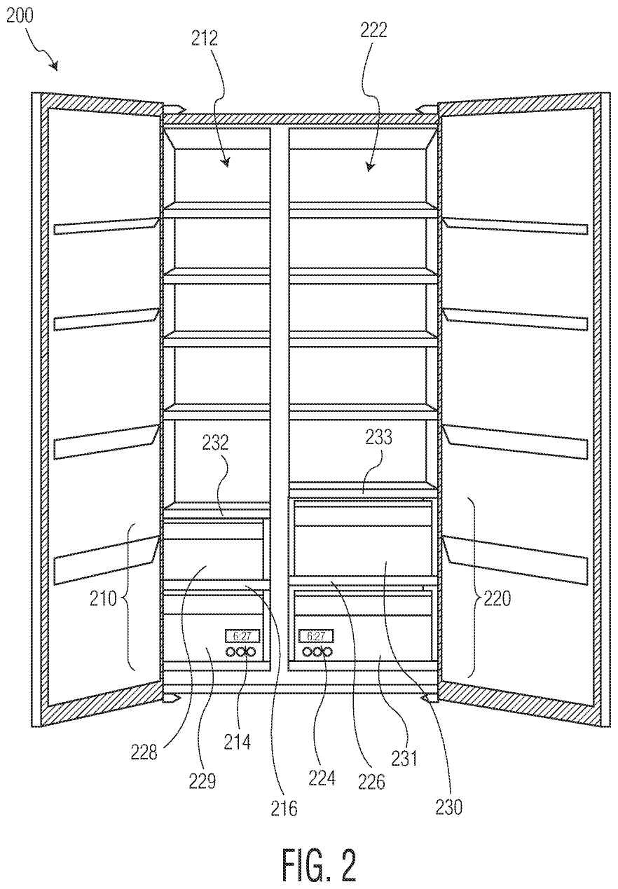

The defrosting system 100 of FIG. 1 is embodied as a counter-top type of appliance. In a further embodiment, the defrosting system 100 also may include components and functionality for performing microwave cooking operations. Alternatively, components of a defrosting system may be incorporated into other types of systems or appliances. For example, FIG. 2 is a perspective view of a refrigerator/freezer appliance 200 that includes other example embodiments of defrosting systems 210, 220. More specifically, defrosting system 210 is shown to be incorporated within a freezer compartment 212 of the system 200, and defrosting system 220 is shown to be incorporated within a refrigerator compartment 222 of the system. An actual refrigerator/freezer appliance likely would include only one of the defrosting systems 210, 220, but both are shown in FIG. 2 to concisely convey both embodiments.

Similar to the defrosting system 100, each of defrosting systems 210, 220 includes two defrosting cavities, a control panel 214, 224, one or more RF signal sources (e.g., RF signal source 340, FIG. 3), a power supply (e.g., power supply 350, FIG. 3), a first electrode (e.g., electrode 170, 370, FIGS. 1, 3) within a fixed shelf 216, 226, power detection circuitry (e.g., power detection circuitry 380, FIG. 3), and a system controller (e.g., system controller 330, FIG. 3). For example, each of the two defrosting cavities of system 210 may be defined by interior surfaces of bottom, side, front, top and/or back walls of one of drawers 228, 229, and either an interior top surface or an interior bottom surface of the fixed shelf 216, under which or over which the drawer 228, 229 slides. Similarly, each of the two defrosting cavities of system 220 may be defined by interior surfaces of bottom, side, front, top and/or back walls of one of drawers 230, 231, and either an interior top surface or an interior bottom surface of the fixed shelf 226, under which or over which the drawer 230, 231 slides. When the drawers 229, 231 are slid fully under its respective shelf 215, 226, the drawer 229, 231 and shelf 216, 226 define two enclosed air cavities. When the drawers 228, 230 are slid fully over its respective shelf 216, 226, the drawer 228, 230, shelf 216, 226, and another fixed shelf 232, 233 above the drawer 228, 230 define two additional enclosed air cavities. The components and functionalities of the defrosting systems 210, 220 may be substantially the same as the components and functionalities of defrosting system 100, in various embodiments. In addition, according to an embodiment, each of the defrosting systems 210, 220 may have sufficient thermal communication with the freezer or refrigerator compartment 212, 222, respectively, in which the system 210, 220 is disposed. In such an embodiment, after completion of a defrosting operation, the load(s) may be maintained at a safe temperature (i.e., a temperature at which food spoilage is retarded) until removal of the load(s) from the system 210, 220. More specifically, upon completion of a defrosting operation by the freezer-based defrosting system 210, the cavity within which a given defrosted load is contained may thermally communicate with the freezer compartment 212, and if the load is not promptly removed from the cavity, the load may re-freeze. Similarly, upon completion of a defrosting operation by the refrigerator-based defrosting system 220, the cavity within which a given defrosted load is contained may thermally communicate with the refrigerator compartment 222, and if the load is not promptly removed from the cavity, the load may be maintained in a defrosted state at the temperature within the refrigerator compartment 222. For example, maintaining the cavities under the shelves 216, 226, 232, 233 near a target temperature may be considered a “normal operation” of the refrigerator/freezer appliance 200 that includes the refrigerator compartment 222 and the freezer compartment 212. The defrosting operation may be considered different from the normal operation of the refrigerator/freezer appliance 200.

Those of skill in the art would understand, based on the description herein, that embodiments of defrosting systems may be incorporated into systems or appliances having other configurations, as well. Accordingly, the above-described implementations of defrosting systems in a stand-alone appliance, a microwave oven appliance, a freezer, and a refrigerator are not meant to limit use of the embodiments only to those types of systems.

Although the defrosting systems 100, 200 are shown with their components in particular relative orientations with respect to one another, it should be understood that the various components may be oriented differently, as well. In addition, the physical configurations of the various components may be different. For example, the control panels 120, 214, 224 may have more, fewer, or different user interface elements, and/or the user interface elements may be differently arranged. As another example, control panels 214, 224 may be disposed in/on other (e.g., non-removable) interior or exterior structures of the freezer compartment 212 or the refrigerator compartment 222, rather than being included as part of the drawers 229, 231. In addition, although a substantially cubic defrosting cavity 110 is illustrated in FIG. 1, it should be understood that a defrosting cavity may have a different shape, in other embodiments (e.g., cylindrical, and so on). Further, the defrosting systems 100, 210, 220 may include additional components (e.g., a fan, a stationary or rotating plate, a tray, an electrical cord, and so on) that are not specifically depicted in FIGS. 1, 2.

FIG. 3 is a simplified block diagram of a defrosting system 300 (e.g., defrosting system 100, 210, 220, FIGS. 1, 2), in accordance with an example embodiment. Defrosting system 300 includes two defrosting cavities 310, 311, user interface 320, system controller 330, RF signal source 340, power supply and bias circuitry 350, variable impedance matching network 360, electrode 370, and power detection circuitry 380, in an embodiment. In addition, in other embodiments, defrosting system 300 may include temperature sensor(s), infrared (IR) sensor(s), and/or weight sensor(s) 390, although some or all of these sensor components may be excluded. It should be understood that FIG. 3 is a simplified representation of a defrosting system 300 for purposes of explanation and ease of description, and that practical embodiments may include other devices and components to provide additional functions and features, and/or the defrosting system 300 may be part of a larger electrical system.

User interface 320 may correspond to a control panel (e.g., control panel 120, 214, 224, FIGS. 1, 2), for example, which enables a user to provide inputs to the system regarding parameters for a defrosting operation (e.g., characteristics of the load(s) to be defrosted, and so on), start and cancel buttons, mechanical controls (e.g., a door/drawer open latch), and so on. In addition, the user interface may be configured to provide user-perceptible outputs indicating the status of a defrosting operation (e.g., a countdown timer, visible indicia indicating progress or completion of the defrosting operation, and/or audible tones indicating completion of the defrosting operation) and other information.

System controller 330 may include one or more general purpose or special purpose processors (e.g., a microprocessor, microcontroller, Application Specific Integrated Circuit (ASIC), and so on), volatile and/or non-volatile memory (e.g., Random Access Memory (RAM), Read Only Memory (ROM), flash, various registers, and so on), one or more communication busses, and other components. According to an embodiment, system controller 330 is coupled to user interface 320, RF signal source 340, variable impedance matching network 360, power detection circuitry 380, and sensors 390 (if included). System controller 330 is configured to receive signals indicating user inputs received via user interface 320, and to receive forward and reflected power measurements from power detection circuitry 380. Responsive to the received signals and measurements, and as will be described in more detail later, system controller 330 provides control signals to the power supply and bias circuitry 350 and to the RF signal generator 342 of the RF signal source 340. In addition, system controller 330 provides control signals to the variable impedance matching network 360, which cause the network 360 to change its state or configuration.

Defrosting cavities 310, 311 include a capacitive defrosting arrangement with first, second, and third parallel plate electrodes that are separated by air cavities within which one or both of loads 316, 317 that are intended to be defrosted may be placed. For example, a first electrode 370 may be positioned between the air cavities of the defrosting cavities 310, 311, and second and third electrodes may be provided by a portion of a containment structure 312. More specifically, the containment structure 312 may include bottom, top, and side walls, the interior surfaces of which define the cavities 310, 311 (e.g., cavities 110, 111, FIG. 1). According to an embodiment, the cavities 310, 311 may both be sealed (e.g., with a door 116, FIG. 1 or by sliding a drawer 228, 229, 230, 231 closed under a shelf 216, 226, 232, 233, FIG. 2) to contain the electromagnetic energy that is introduced into the cavity 310 during a defrosting operation. The system 300 may include one or more interlock mechanisms that ensure that the seal is intact during a defrosting operation. If one or more of the interlock mechanisms indicates that the seal is breached, the system controller 330 may cease the defrosting operation. According to an embodiment, the containment structure 312 is at least partially formed from conductive material, and the conductive portion(s) of the containment structure may be grounded via one or more connections to one or more ground reference terminals. Either way, the containment structure 312 (or at least the portions of the containment structure 312 that are parallel with the first electrode 370) functions as second and third electrodes of the capacitive defrosting arrangement. For example, a bottom wall of the containment structure 312 may be at least partially conductive and may form the second electrode, and a top wall of the containment structure 312 may be at least partially conductive and may form the third electrode. To avoid direct contact between the load 316 and the grounded bottom wall of the cavity 310, a non-electrically conductive (e.g., electrically insulative) barrier 314 may be positioned over (e.g., and optionally in direct contact with) a top surface of the bottom wall of the cavity 310. To avoid direct contact between the load 317 and the first electrode 370, a non-electrically conductive (e.g., electrically insulative) barrier 315 may be positioned over (e.g., and optionally in direct contact with) the first electrode 370.

Defrosting cavities 310, 311 and any loads 316, 317 (e.g., food, liquids, and so on) positioned in the defrosting cavities 310, 311 present a cumulative load for the electromagnetic energy (or RF power) that is radiated into the cavities 310, 311 by the first electrode 370. More specifically, the cavities 310, 311 and the loads 316, 317 each present an impedance to the system, referred to herein as a “cavity input impedance.” The cavity input impedance associated with each of the cavities 310, 311 changes during a defrosting operation as the temperature of the loads 316, 317 increase. The impedance of many types of food loads changes with respect to temperature in a somewhat predictable manner as the food load transitions from a frozen state to a defrosted state. According to an embodiment, based on reflected and forward power measurements from the power detection circuitry 380, the system controller 330 is configured to identify a point in time during a defrosting operation when the rate of change of cavity input impedance indicates that the load 316 is approaching 0° Celsius, at which time the system controller 330 may terminate the defrosting operation. The first electrode 370 is electrically coupled to the RF signal source 340 through a variable impedance matching network 360 and a transmission path 348, in an embodiment. As will be described in more detail later, the variable impedance matching circuit 360 is configured to perform an impedance transformation from an impedance of the RF signal source 340 to an input impedance of defrosting cavities 310, 311 as modified by the loads 316, 317. In an embodiment, the variable impedance matching network 360 includes a network of passive components (e.g., inductors, capacitors, resistors). In addition, the variable impedance matching network 360 may include a plurality of variable impedance networks, which may be located outside of the cavities 310, 311. The impedance value provided by each of the variable impedance networks is established using control signals from the system controller 330, as will be described in more detail later. In any event, by changing the state of the variable impedance matching network 360 over the course of a defrosting operation to dynamically match the ever-changing cavity input impedances, the amount of RF power that is absorbed by the loads 316, 317 may be maintained at a high level despite variations in the load impedances during the defrosting operation.

According to an embodiment, RF signal source 350 includes an RF signal generator 342 and a power amplifier (e.g., including one or more power amplifier stages 344, 346). In response to control signals provided by system controller 330, RF signal generator 342 is configured to produce an oscillating electrical signal having a frequency in the ISM (industrial, scientific, and medical) band, although the system could be modified to support operations in other frequency bands, as well. The RF signal generator 342 may be controlled to produce oscillating signals of different power levels and/or different frequencies, in various embodiments. For example, the RF signal generator 342 may produce a signal that oscillates in a range of about 3.0 megahertz (MHz) to about 300 MHz. Some desirable frequencies may be, for example, 13.56 MHz (+/−5 percent), 27.125 MHz (+/−5 percent), and 40.68 MHz (+/−5 percent). In one particular embodiment, for example, the RF signal generator 342 may produce a signal that oscillates in a range of about 40.66 MHz to about 40.70 MHz and at a power level in a range of about 10 decibels (dB) to about 15 dB. Alternatively, the frequency of oscillation and/or the power level may be lower or higher.

In the embodiment of FIG. 3, the power amplifier includes a driver amplifier stage 344 and a final amplifier stage 346. The power amplifier is configured to receive the oscillating signal from the RF signal generator 342, and to amplify the signal to produce a significantly higher-power signal at an output of the power amplifier. For example, the output signal may have a power level in a range of about 100 watts to about 400 watts or more. The gain applied by the power amplifier may be controlled using gate bias voltages and/or drain supply voltages provided by the power supply and bias circuitry 350 to each amplifier stage 344, 346. More specifically, power supply and bias circuitry 350 provides bias and supply voltages to each RF amplifier stage 344, 346 in accordance with control signals received from system controller 330.

In an embodiment, each amplifier stage 344, 346 is implemented as a power transistor, such as a field effect transistor (FET), having an input terminal (e.g., a gate or control terminal) and two current carrying terminals (e.g., source and drain terminals). Impedance matching circuits (not illustrated) may be coupled to the input (e.g., gate) of the driver amplifier stage 344, between the driver and final amplifier stages 346, and/or to the output (e.g., drain terminal) of the final amplifier stage 346, in various embodiments. In an embodiment, each transistor of the amplifier stages 344, 346 includes a laterally diffused metal oxide semiconductor FET (LDMOSFET) transistor. However, it should be noted that the transistors are not intended to be limited to any particular semiconductor technology, and in other embodiments, each transistor may be realized as a gallium nitride (GaN) transistor, another type of MOSFET transistor, a bipolar junction transistor (BJT), or a transistor utilizing another semiconductor technology. In FIG. 3, the power amplifier arrangement is depicted to include two amplifier stages 344, 346 coupled in a particular manner to other circuit components. In other embodiments, the power amplifier arrangement may include other amplifier topologies and/or the amplifier arrangement may include only one amplifier stage, or more than two amplifier stages. For example, the power amplifier arrangement may include various embodiments of a single ended amplifier, a double ended amplifier, a push-pull amplifier, a Doherty amplifier, a Switch Mode Power Amplifier (SMPA), or another type of amplifier.

Power detection circuitry 380 is coupled along the transmission path 348 between the output of the RF signal source 340 and the input to the variable impedance matching network 360, in an embodiment. In an alternate embodiment, power detection circuitry 380 may be coupled to the transmission path 349 between the output of the variable impedance matching network 360 and the first electrode 370. Either way, power detection circuitry 380 is configured to monitor, measure, or otherwise detect the power of the forward signals (i.e., from RF signal source 340 toward first electrode 370) and the reflected signals (i.e., from first electrode 370 toward RF signal source 340) traveling along the transmission path 348. In some embodiments, the power detection circuitry 380 may detect only the power of the reflected signals.

Power detection circuitry 380 supplies signals conveying the magnitudes of the forward and reflected signal power to system controller 330. System controller 330, in turn, may calculate a ratio of reflected signal power to forward signal power, or the S11 parameter. As will be described in more detail below, when the reflected to forward power ratio exceeds a threshold, this indicates that the system 300 is not adequately matched, and that energy absorption by the load 316 and/or the load 317 may be sub-optimal. In such a situation, system controller 330 orchestrates a process of altering the state of the variable impedance matching network until the reflected to forward power ratio decreases to a desired level, thus re-establishing an acceptable match and facilitating more optimal energy absorption by the load 316. As mentioned above, some embodiments of defrosting system 300 may include temperature sensor(s), IR sensor(s), and/or weight sensor(s) 390. The temperature sensor(s) and/or IR sensor(s) may be positioned in locations that enable the temperature of the load 316 and/or the temperature of the load 317 to be sensed during the defrosting operation. When provided to the system controller 330, the temperature information enables the system controller 330 to alter the power of the RF signal supplied by the RF signal source 340 (e.g., by controlling the bias and/or supply voltages provided by the power supply and bias circuitry 350), to adjust the state of the variable impedance matching network 360, and/or to determine when the defrosting operation should be terminated. The weight sensor(s) are positioned under the load 316 and/or under the load 317, and are configured to provide an estimate of the weight of the load 316 and/or an estimate of the weight of the load 317 to the system controller 330. The system controller 330 may use this information, for example, to determine a desired power level for the RF signal supplied by the RF signal source 340, to determine an initial setting for the variable impedance matching network 360, and/or to determine an approximate duration for the defrosting operation.

As discussed above, the variable impedance matching network 360 is used to match the input impedance of the defrosting cavity 310 plus load 316, 317 to maximize, to the extent possible, the RF power transfer into the load 316, 317. The initial impedance of the defrosting cavity 310 and each load 316, 317 may not be known with accuracy at the beginning of a defrosting operation. Further, the impedance of each load 316, 317 changes during a defrosting operation as each load 316, 317 warms up. According to an embodiment, the system controller 330 may provide control signals to the variable impedance matching network 360, which cause modifications to the state of the variable impedance matching network 360. This enables the system controller 330 to establish an initial state of the variable impedance matching network 360 at the beginning of the defrosting operation that has a relatively low reflected to forward power ratio, and thus a relatively high absorption of the RF power by each load 316, 317. In addition, this enables the system controller 330 to modify the state of the variable impedance matching network 360 so that an adequate match may be maintained throughout the defrosting operation, despite changes in the impedance of each load 316, 317.

According to an embodiment, the variable impedance matching network 360 may include a network of passive components, and more specifically a network of fixed-value inductors and/or capacitors (e.g., lumped inductive components or lumped capacitive components) and variable inductors and/or variable capacitors (or variable inductance networks and/or variable capacitance networks). As used herein, the term “inductor” means a discrete inductor or a set of inductive components that are electrically coupled together without intervening components of other types (e.g., resistors or capacitors). As used herein, the term “capacitor” means a discrete capacitor or a set of capacitive components that are electrically coupled together without intervening components of other types (e.g., resistors or inductors).

The variable impedance matching network 360 may essentially include two portions: one portion to match the RF signal source (or the final stage power amplifier); and another portion to match the cavity plus load.

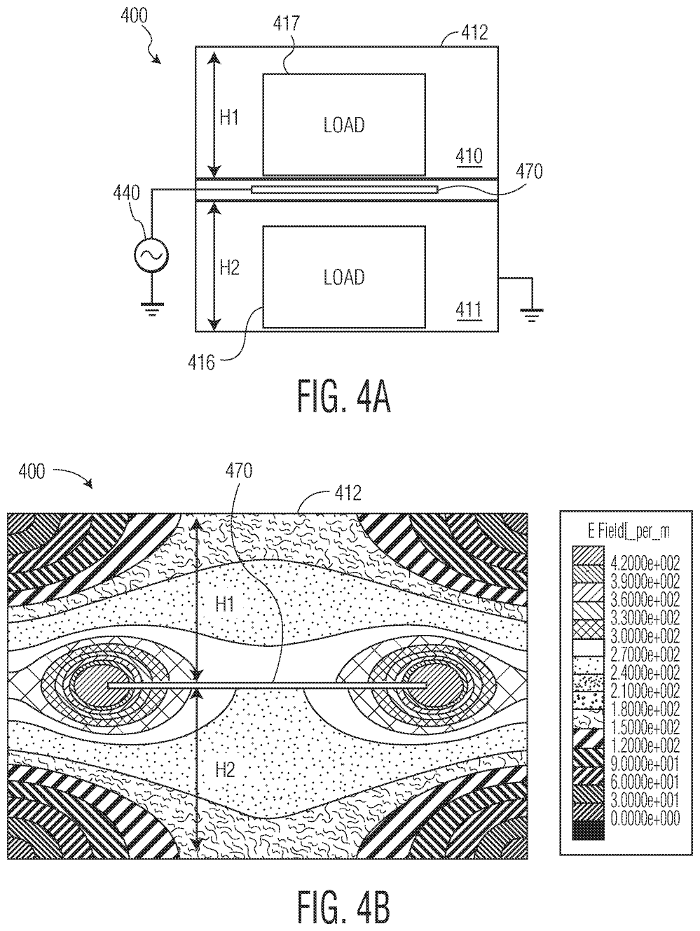

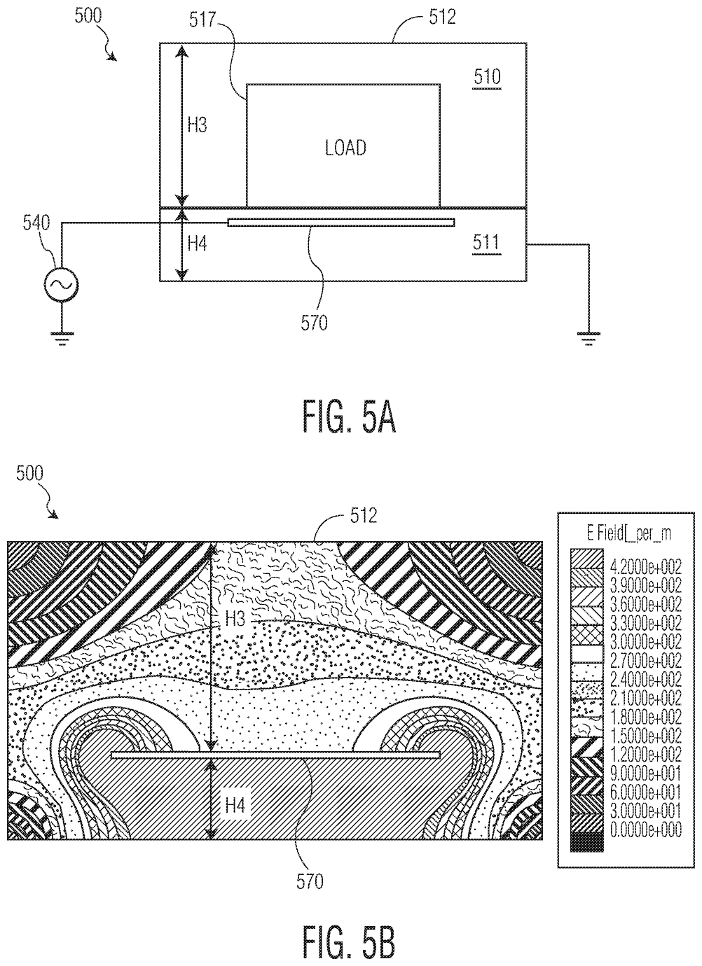

A particular physical configuration of a dual-chamber defrosting system in comparison to that of a single-chamber defrosting system will now be described in conjunction with FIGS. 4A, 4B, 5A, and 5B. More particularly, FIG. 4A is a cross-sectional, side view of a dual-chamber defrosting system 400, in accordance with an example embodiment. FIG. 4B shows electric field magnitudes within the defrosting system 400. FIG. 5A is a cross-sectional side view of a single chamber defrosting system 500 (e.g., defrosting systems 100, 210, 220, 300, FIGS. 1-3. FIG. 5B shows electric field magnitudes within the defrosting system 500.

The defrosting system 400 generally includes a defrosting cavity 410, a defrosting cavity 411, a user interface (e.g., user interface 320, FIG. 3), a system controller (e.g., system controller 330, FIG. 3), an RF signal source 440, power supply and bias circuitry (e.g., circuitry 350, FIG. 3), power detection circuitry (e.g., power detection circuitry 380, FIG. 3), a variable impedance matching network (e.g., network 360, FIG. 3), a first electrode 470 that may be disposed within electrically non-conductive material (e.g., embedded in a sheet, platform, or shelf formed from the electrically non-conductive material or disposed between two sections of the electrically non-conductive material), and second and third electrodes formed by a containment structure 412, in an embodiment. In some other embodiments, the second and third electrodes may be separate, grounded conductive plates that are parallel with the top and bottom walls of the containment structure 412. In addition, in some embodiments, defrosting system 400 may include weight sensor(s), temperature sensor(s), and/or IR sensor(s) (e.g., sensors 390, FIG. 3).

The height H1 represents a distance between the first electrode 470 and a second electrode (e.g., a portion of the top wall of the containment structure 412). The height H2 represents a distance between the first electrode 470 and a third electrode (e.g., a portion of the bottom wall of the containment structure 412). The height H1 of the defrosting cavity 410 may be approximately the same as the height H2 of the defrosting cavity 411, in an embodiment. For example, each of heights H1 and H2 may be in a range of about 5 centimeters (cm) to about 30 cm (e.g., about 10 cm), although the heights H1, H2 may be smaller or larger, as well. For example, the containment structure 412 and the electrode 470 may be positioned such that the height H1 is within a predetermined percentage (e.g., 1% to 5% or less) of the height H2.

The containment structure 412 may define three interior areas: the defrosting cavity 410, the defrosting cavity 411, and a circuit housing area (not shown). The containment structure 412 may include bottom, top, and side walls, where different walls and/or different portions of the walls may define the interior boundaries of each of the defrosting cavities 410 and 411. Each of the defrosting cavities 410 and 411 may include a capacitive defrosting arrangement with a first capacitive plate (the first electrode 470), a second capacitive plate (e.g., some or all of the top wall of the containment structure 412), and a third capacitive plate (e.g., some or all of the bottom wall of the containment structure 412). The first electrode 470 may be separated from the top wall of the containment structure by an air cavity in which a load 417 to be defrosted may be placed. The first electrode 470 may be separated from the bottom wall of the containment structure by another air cavity in which a load 416 to be defrosted may be placed. The first electrode 470 is electrically coupled to the RF signal source 440, and receives RF energy from the RF signal source 440 during heating operations of the defrosting system 400. When RF energy is applied to the first electrode 470 by the RF signal source 440, a first electric field is created between the first electrode 470 and the portion (e.g., top and/or side walls) of the containment structure 412 that forms the second electrode, and a second electric field is created between the first electrode 470 and the portion (e.g., bottom and/or side walls) of the containment structure 412 that forms the third electrode.

As shown in FIG. 4B, when RF energy is applied to the first electrode 470 during a heating operation of the defrosting system 400, the magnitude of the electric field at various locations within the defrosting cavity 410 may substantially match (or mirror) the magnitude of the electric field at corresponding locations within the defrosting cavity 411. This may be caused, in part, by the height H1 being approximately equal to the height H2, resulting in a first parasitic capacitance C1 between the electrode 470 and a top electrode (e.g., the top wall of the containment structure 412) being approximately equal to a second parasitic capacitance C2 between the electrode 470 and a bottom electrode (e.g., the bottom wall of the containment structure 412). For two loads 416, 417 of similar mass, such similarities in electric field magnitudes within the defrosting cavity 410 and the defrosting cavity 411 may result in a similar rate of thermal increase in the load 416 as in the load 417.

According to an embodiment, the containment structure 412 is at least partially formed from conductive material, and the conductive portion(s) of the containment structure may be grounded (e.g., via a connection to a ground reference terminal) to provide a ground reference for various electrical components of the system.

Alternatively, at least the portion of the containment structure 412 that corresponds to the second and third electrodes (e.g., all or portions of the top wall and the bottom wall) may be formed from conductive material and grounded. To avoid direct contact between the load 416 and the conductive portions of the bottom wall of the containment structure 412, a non-conductive barrier (e.g., barrier 314, FIG. 3) may be positioned over the bottom wall of the containment structure 412. To avoid direct contact between the load 417 and the electrode 470, another non-conductive barrier (e.g., barrier 315, FIG. 3) may be positioned over the first electrode 470.

When included in the system 400, weight sensor(s) may be positioned under the load 416 and/or the load 417. The weight sensor(s) may be configured to provide an estimate of the weight of the load 416 and/or the load 417 to the system controller. The temperature sensor(s) and/or IR sensor(s) may be positioned in locations that enable the temperature of the load 416 and/or the load 417 to be sensed before, during, and after a defrosting operation. According to an embodiment, the temperature sensor(s) and/or IR sensor(s) are configured to provide load temperature estimates to the system controller.

Some or all of the various components of the system controller, the RF signal source 440, the power supply and bias circuitry, the power detection circuitry, and portions of the variable impedance matching network may be coupled to a common substrate within the circuit housing area of the containment structure 412, in an embodiment. According to an embodiment, the system controller is coupled to the user interface, RF signal source 440, variable impedance matching network, and power detection circuitry through various conductive interconnects on or within the common substrate. In addition, the power detection circuitry is coupled along the transmission path between the output of the RF signal source 440 and the input to the variable impedance matching network, in an embodiment. For example, the common substrate may include a microwave or RF laminate, a polytetrafluoroethylene (PTFE) substrate, a printed circuit board (PCB) material substrate (e.g., FR-4), an alumina substrate, a ceramic tile, or another type of substrate. In various alternate embodiments, various ones of the components may be coupled to different substrates with electrical interconnections (e.g., cables) between the substrates and components. In still other alternate embodiments, some or all of the components may be coupled to a cavity wall, rather than being coupled to a distinct substrate. The first electrode 470 is electrically coupled to the RF signal source 440 through the variable impedance matching network and a transmission path, in an embodiment. As discussed previously, the variable impedance matching network includes variable impedance (e.g., inductance, capacitance, and/or resistance) networks and a plurality of fixed-value lumped impedance elements (e.g., lumped inductors, capacitor, and/or resistors). In an embodiment, the variable impedance networks and lumped impedance elements are coupled to the common substrate and located within the circuit housing area of the containment structure 412. In another embodiment, the variable impedance networks may be housed in a circuit housing area of the containment structure 412 that is separate from the circuit housing are in which the variable impedance networks are housed. Conductive structures (e.g., conductive vias or other structures) may provide for electrical communication between the circuitry within the circuit housing area(s).

Turning to FIGS. 5A and 5B, a more conventional defrosting system 500 generally includes a defrosting cavity 510, a chamber 511, a user interface (not shown), a system controller (not shown), an RF signal source 540, power supply and bias circuitry (not shown), power detection circuitry (not shown), a variable impedance matching network (not shown), a first electrode 570, and second and third electrodes formed by a containment structure 512. Some or all of the system controller, the first electrode 570, the power detection circuitry, the power supply and bias circuitry, and the variable impedance matching network may be disposed within the chamber 511. For example, the chamber 511 may be used exclusively for storing electronic components and/or other components of the defrosting system 500, and may not be used as a defrosting chamber for a load.

The containment structure 512 may include bottom, top, and side walls, which may define portions of the defrosting cavity 510 and the chamber 511. The defrosting cavity 510 may include a capacitive defrosting arrangement with a first capacitive plate (a first electrode 570) and a second capacitive plate (portions of the containment structure 512, such as a portion of the top wall) that are separated by an air cavity in which a load 517 to be defrosted may be placed. The first electrode 570 is electrically coupled to the RF signal source 540, and receives RF energy from the RF signal source 540 during heating operations of the defrosting system 500. The height H3 (e.g., 5-30 cm) of the defrosting cavity 510 may be greater than the height H4 (e.g., 2-10 cm) of the chamber 511, in the present example.

As shown in FIG. 5B, during a heating operation of the defrosting system 500, the electric field strength between the electrode 570 and the top wall of the containment structure 512 is less (e.g., about 30-50% less) than the electric field strength between the electrode 570 and the bottom wall of the containment structure 512 when the height H4 is substantially smaller than the height H3 (e.g., with the height H3 being approximately 10 cm and the height H4 being approximately 4 cm in the present example). This difference in electric field magnitude may be partially caused by a first parasitic capacitance C1 that exists between the electrode 570 and the top wall of the containment structure 512 being substantially lower than a second parasitic capacitance C2 that exists between the electrode 570 and the bottom wall of the containment structure 512. This difference in parasitic capacitances C1 and C2 within the defrosting system 500 may decrease the defrosting efficiency for the defrosting system 500. Additionally, space utilization efficiency may be non-ideal in the defrosting system 500 at least because the chamber 511 is dedicated to component storage, and is unavailable to be used as a defrosting cavity.

Aspects of the dual-chamber defrosting system 400 of FIGS. 4A, 4B and the single-chamber defrosting system 500 of FIGS. 5A, 5B will now be compared.

First, defrosting efficiency will be considered for each system. Defrosting efficiency may be defined as the percentage or ratio of the amount of energy that is absorbed by one or more loads to the total amount of energy that is supplied by an RF signal source (e.g., RF signal source 440, 540). For example, assuming that load resistance (e.g., about 1 ohm for food loads) is substantially less than capacitive reactance of a given defrosting cavity (e.g., about 10 picofarads (pF), 391 ohms at about 40.68 megahertz (MHz)) the total impedance Zload of a given upper defrosting cavity (e.g., cavity 410, 510) may be approximately modeled according to EQ. 1:

$$Zload \approx {R ( \frac{1}{1 + \frac{C 2}{C 1}} )}^{2} + \frac{1}{j ω ( C 1 + C 2 )} \qquad EQ . 1$$

where R represents the resistance of the load, C1 represents a parasitic capacitance between the electrode (e.g., electrode 470, 570) and the top wall of the containment structure (e.g., containment structure 412, 512), and C2 represents a parasitic capacitance between the electrode and the bottom wall of the containment structure. The real part of Zload represents the energy absorption that contributes to increasing the temperature of a given load. The higher that the real part of Zload is, the more energy that could be absorbed by the load (i.e., resulting in higher defrosting efficiency).

For the purpose of this comparison, an embodiment of the dual-chamber defrosting system 400 in which the defrosting cavity heights H1 and H2 are about the same (e.g., H1 and H2 may each be about 10 cm) will be considered, and an embodiment of the single-chamber defrosting system 500 in which the defrosting cavity height H3 will be assumed to be larger than the chamber height H4 (e.g., H3 may be about 10 cm and H4 may be about 4 cm) will be considered.

In the single-chamber defrosting system 500, because the defrosting cavity height H3 is larger than the chamber height H4, the first parasitic capacitance C1 will be smaller than the second parasitic capacitance C2 in the single-chamber defrosting system 500, resulting in a Zload having a comparatively smaller real part, therefore resulting in a comparatively lower defrosting efficiency.

In the dual-chamber defrosting system 400, because the defrosting cavity height H1 is about the same as the defrosting cavity height H2, the first parasitic capacitance C1 will be approximately equal to the second parasitic capacitance C2 in the dual-chamber defrosting system 400, resulting in a Zload having a comparatively larger real part, therefore resulting in a comparatively higher defrosting efficiency.

It should be understood that if the cavity height H4 of the single-chamber defrosting system 500 were increased to be roughly equal to the defrosting cavity height H3, then the defrosting efficiency of the single-chamber defrosting system 500 would be about the same as that of the dual-chamber defrosting system 400, but at the cost of space utilization efficiency of the single-chamber defrosting system 500.

Next, the space utilization efficiency will be considered for each system. Space utilization efficiency, as used here, refers to the percentage or ratio of the volume of a defrosting system that is available to contain a load to the total volume of the defrosting system.

For the dual-chamber defrosting system 400, the space utilization efficiency is nearly 100%, if the space needed for the electrode 470 and any corresponding electrically insulative/non-electrically conductive material (e.g., barrier 315, FIG. 3) is ignored, as the cavities on either side of the electrode 470 are available to contain and defrost loads.

For the single-chamber defrosting system 500, the space utilization efficiency is non-ideal because the chamber 511 is dedicated to housing components of the system. For example, if the defrosting cavity height H3 were about 10 cm and the chamber height H4 were about 4 cm, the space utilization efficiency would be about 71.4%. If the height H4 were increased to 10 cm from 4 cm, the space utilization efficiency would decrease to about 50%. As described above, increasing the height H4 would improve defrosting efficiency at the cost of space utilization efficiency. As shown, there is a tradeoff that exists between space utilization efficiency and defrosting efficiency for the single-chamber defrosting system 500.

Thus, when considering the embodiments of the present example, the dual-chamber defrosting system 400 may provide improved space utilization efficiency and/or defrosting efficiency when compared to the single chamber defrosting system 500.

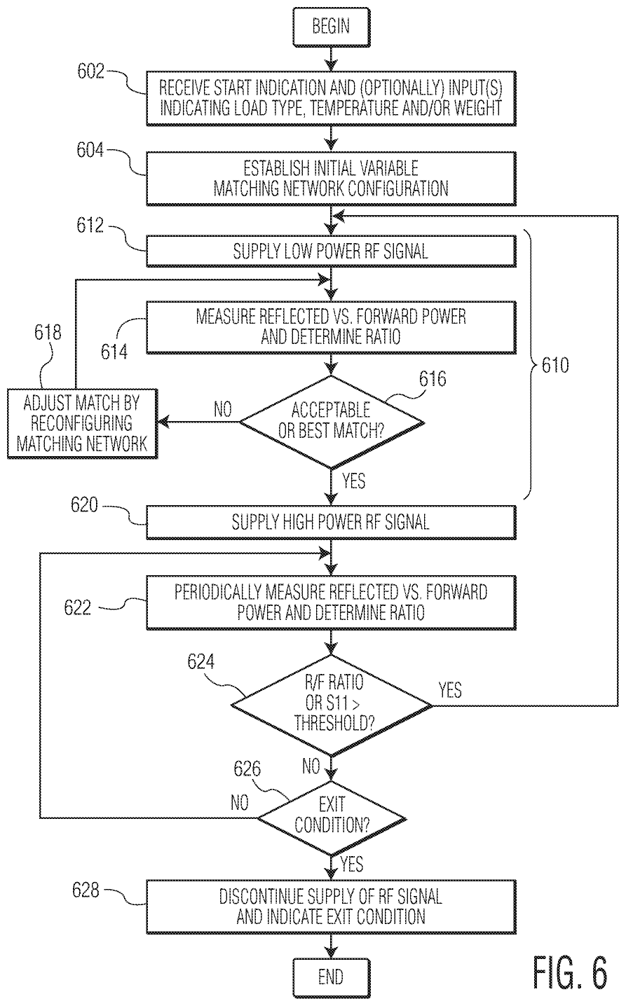

Now that embodiments of the electrical and physical aspects of defrosting systems have been described, various embodiments of methods for operating such defrosting systems will now be described in conjunction with FIG. 6. More specifically, FIG. 6 is a flowchart of a method of operating a defrosting system (e.g., system 100, 210, 220, 300, 400, FIGS. 1-4B) with dynamic load matching, in accordance with an example embodiment.

The method may begin, in block 602, when the system controller (e.g., system controller 330, FIG. 3) receives an indication that a defrosting operation should start. Such an indication may be received, for example, after a user has place one or more loads (e.g., load(s) 316, 317, 416, 417, FIGS. 3, 4) into the system's defrosting cavities (e.g., cavities 310, 311, 410, 411 FIGS. 3, 4), has sealed the cavities (e.g., by closing a door or drawer(s)), and has pressed a start button (e.g., of the user interface 320, FIG. 3). In an embodiment, sealing of the cavity may engage one or more safety interlock mechanisms, which when engaged, indicate that RF power supplied to the cavity will not substantially leak into the environment outside of the cavity. As will be described later, disengagement of a safety interlock mechanism may cause the system controller immediately to pause or terminate the defrosting operation.

According to various embodiments, the system controller optionally may receive additional inputs indicating the load type(s) (e.g., meats, liquids, or other materials), the initial load temperature(s), and/or the load weight(s). For example, information regarding the load type may be received from the user through interaction with the user interface (e.g., by the user selecting from a list of recognized load types). Alternatively, the system may be configured to scan a barcode visible on the exterior of each load, or to receive an electronic signal from an RFID device on or embedded within each load. Information regarding the initial load temperature may be received, for example, from one or more temperature sensors and/or IR sensors (e.g., sensors 390, FIG. 3) of the system. Information regarding the load weight may be received from the user through interaction with the user interface, or from one or more weight sensors (e.g., sensor 390, FIG. 3) of the system. As indicated above, receipt of inputs indicating the load type(s), initial load temperature(s), and/or load weight(s) is optional, and the system alternatively may not receive some or all of these inputs.

In block 604, the system controller provides control signals to the variable matching (e.g., network 360, FIG. 3) to establish an initial configuration or state for the variable matching network. The control signals affect the impedance transformations provided by variable impedance networks within the variable matching network by varying the component values of one or more variable inductors and/or capacitors. For example, the control signals may affect the states of bypass switches within one or more of the variable impedance networks, which are responsive to the control signals from the system, and which cause inductors and/or capacitors to be switched into or out of the variable impedance networks.

As also discussed previously, a first portion of the variable matching network may be configured to provide a match for the RF signal source (e.g., RF signal source 340, FIG. 3) or the final stage power amplifier (e.g., power amplifier 346, FIG. 3), and a second portion of the variable matching network may be configured to provide a match for the cavity (e.g., cavity 310, FIG. 3) plus the load or loads (e.g., loads 316, 317, FIG. 3). For example, a first variable impedance network may be configured to provide the RF signal source match, and a second variable impedance network may be configured to provide the cavity plus load match.

It has been observed that a best initial overall match for a frozen load (i.e., a match at which a maximum amount of RF power is absorbed by the load) typically has a relatively high inductance for the cavity matching portion of the matching network, and a relatively low inductance for the RF signal source matching portion of the matching network.

According to an embodiment, to establish the initial configuration or state for the variable matching network in block 604, the system controller sends control signals to the first and second variable impedance networks to adjust the impedance transformations provided by the networks. The system controller may determine how large or how small the impedance transformations are set based on load type/weight/temperature information known to the system controller a priori. For embodiments in which the variable impedance networks include variable inductor networks or variable capacitor networks, if no a priori load type/weight/temperature information is available to the system controller, the system controller may select a relatively low default inductance or high default capacitance values for the RF signal source match and a relatively high default inductance or low default capacitance for the cavity match.

Assuming, however, that the system controller does have a priori information regarding the load characteristics, the system controller may attempt to establish an initial configuration near the optimal initial matching point. For example, the optimal initial matching point for a given type of load may have a cavity match of about 80 percent of the network's maximum value, and may have an RF signal source match of about 10 percent of the network's maximum value. The system controller may initialize the variable impedance networks such that the cavity matching portion of the variable impedance matching network has a state corresponding to its optimal initial matching point (e.g., about 80 percent of the network's maximum value) and such that the RF signal source matching portion of the variable impedance matching network has a state corresponding to its optimal initial matching point (e.g., about 10 percent of the network's maximum value).

Once the initial variable matching network configuration is established, the system controller may perform a process 610 of adjusting, if necessary, the configuration of the variable impedance matching network to find an acceptable or best match based on actual measurements that are indicative of the quality of the match. According to an embodiment, this process includes causing the RF signal source (e.g., RF signal source 340, 440, FIGS. 3, 4) to supply a relatively low power RF signal through the variable impedance matching network to the first electrode (e.g., first electrode 170, 370, 470, FIGS. 1, 3, 4), in block 612. The system controller may control the RF signal power level through control signals to the power supply and bias circuitry (e.g., circuitry 350, FIG. 3), where the control signals cause the power supply and bias circuitry to provide supply and bias voltages to the amplifiers (e.g., amplifier stages 344, 346, FIG. 3) that are consistent with the desired signal power level. For example, the relatively low power RF signal may be a signal having a power level in a range of about 10 watts (W) to about 20 W, although different power levels alternatively may be used. A relatively low power level signal during the match adjustment process 610 is desirable to reduce the risk of damaging the cavities or load(s) (e.g., if the initial match were to cause high reflected power), and to reduce the risk of damaging the switching components of the variable impedance networks (e.g., due to arcing across switch contacts within the variable impedance networks).

In block 614, power detection circuitry (e.g., power detection circuitry 380, FIG. 3) then measures the magnitudes of the forward and reflected power (or just the reflected power) along the transmission path (e.g., path 348, FIG. 3) between the RF signal source and the first electrode, and provides those measurements to the system controller. The system controller may then determine a ratio between the reflected and forward signal powers, and may determine the S11 parameter for the system based on the ratio. The system controller may store the calculated ratios and/or S11 parameters for future evaluation or comparison, in an embodiment.

In block 616, the system controller may determine, based on the magnitude of reflected power, the reflected-to-forward signal power ratio, and/or the S11 parameter, whether or not the match provided by the variable impedance matching network is acceptable (e.g., the ratio is 10 percent or less, or compares favorably with some other criteria). Alternatively, the system controller may be configured to determine whether the match is the “best” match. A “best” match may be determined, for example, by iteratively measuring the forward and reflected RF power (or just the reflected power) for all possible impedance matching network configurations (or at least for a defined subset of impedance matching network configurations), and determining which configuration results in the lowest reflected power or reflected-to-forward power ratio.

When the system controller determines that the match is not acceptable or is not the best match, the system controller may adjust the match, in block 618, by reconfiguring the variable impedance matching network. For example, this may be achieved by sending control signals to the variable impedance matching network, which cause the network to increase and/or decrease the variable inductances, capacitances and/or resistances of variable components within the network. After reconfiguring the variable impedance matching network, blocks 614, 616, and 618 may be iteratively performed until an acceptable or best match is determined in block 616.

Once an acceptable or best match is determined, the defrosting operation may commence. Commencement of the defrosting operation includes increasing the power of the RF signal supplied by the RF signal source (e.g., RF signal source 340, 440, FIGS. 3, 4) to a relatively high power RF signal, in block 620. Once again, the system controller may control the RF signal power level through control signals to the power supply and bias circuitry (e.g., circuitry 350, FIG. 3), where the control signals cause the power supply and bias circuitry to provide supply and bias voltages to the amplifiers (e.g., amplifier stages 344, 346, FIG. 3) that are consistent with the desired signal power level. For example, the relatively high power RF signal may be a signal having a power level in a range of about 50 W to about 500 W, although different power levels alternatively may be used.

In block 622, power detection circuitry (e.g., power detection circuitry 380, FIG. 3) then periodically measures magnitudes of the forward and reflected power (or just the reflected power) along the transmission path (e.g., path 348, FIG. 3) between the RF signal source and the first electrode, and provides those measurements to the system controller. The system controller again may determine a ratio between the reflected and forward signal powers, and may determine the S11 parameter for the system based on the ratio. The system controller may store the calculated ratios and/or S11 parameters for future evaluation or comparison, in an embodiment. According to an embodiment, the periodic measurements of the forward and reflected power may be taken at a fairly high frequency (e.g., on the order of milliseconds) or at a fairly low frequency (e.g., on the order of seconds). For example, a fairly low frequency for taking the periodic measurements may be a rate of one measurement every 10 seconds to 20 seconds. In block 624, the system controller may determine, based on one or more measured reflected power magnitudes, calculated reflected-to-forward signal power ratios, and/or one or more calculated S11 parameters, whether or not the match provided by the variable impedance matching network is acceptable. For example, the system controller may use a single reflected power measurement, calculated reflected-to-forward signal power ratio, or S11 parameter in making this determination, or may take an average (or other calculation) of a number of previously-measured or previously-calculated reflected power magnitudes, reflected-to-forward power ratios, or S11 parameters in making this determination. To determine whether or not the match is acceptable, the system controller may compare the reflected power measurement, calculated ratio, and/or S11 parameter to a threshold, for example. For example, in one embodiment, the system controller may compare the calculated reflected-to-forward signal power ratio to a threshold of 10 percent (or some other value). A ratio below 10 percent may indicate that the match remains acceptable, and a ratio above 10 percent may indicate that the match is no longer acceptable. When the calculated measurement, ratio, or S11 parameter is greater than the threshold (i.e., the comparison is unfavorable), indicating an unacceptable match, then the system controller may initiate re-configuration of the variable impedance matching network by again performing process 610.

As discussed previously, the match provided by the variable impedance matching network may degrade over the course of a defrosting operation due to impedance changes of the load or loads (e.g., loads 316, 317, FIG. 3) as the load(s) warms up and change state. For example, over the course of a defrosting operation, an optimal cavity match may be maintained by altering the capacitances, inductances, and/or resistances of variable capacitors, inductors and/or resistors of the variable impedance matching network.

According to an embodiment, in the iterative process 610 of re-configuring the variable impedance matching network, the system controller may initially, when adjusting the match by reconfiguring the variable impedance matching network in block 618, select states for individual or groups of variable capacitors, inductors and/or resistors of the variable impedance matching network that correspond to expected optimal match trajectories (e.g., optimal cavity match and optimal RF signal source match). By selecting variable component values that tend to follow the expected optimal match trajectories in this way, the time to perform the variable impedance matching network reconfiguration process 610 may be reduced, when compared with a reconfiguration process that does not take these tendencies into account.

In actuality, there are a variety of different searching methods that the system controller may employ to re-configure the system to have an acceptable impedance match, including testing all possible variable impedance matching network configurations. Any reasonable method of searching for an acceptable configuration is considered to fall within the scope of the inventive subject matter. In any event, once an acceptable match is determined in block 616, the defrosting operation is resumed in block 620, and the process continues to iterate.

Referring back to block 624, when the system controller determines, based on one or more reflected power measurements, calculated reflected-to-forward signal power ratios, and/or one or more calculated S11 parameters, that the match provided by the variable impedance matching network is still acceptable (e.g., the measurement, calculated ratio, or S11 parameter is less than the threshold, or the comparison is favorable), the system may evaluate whether or not an exit condition has occurred, in block 626. In actuality, determination of whether an exit condition has occurred may be an interrupt driven process that may occur at any point during the defrosting process. However, for the purposes of including it in the flowchart of FIG. 6, the process is shown to occur after block 624. In any event, several conditions may warrant cessation of the defrosting operation. For example, the system may determine that an exit condition has occurred when a safety interlock is breached. Alternatively, the system may determine that an exit condition has occurred upon expiration of a timer that was set by the user (e.g., through user interface 320, FIG. 3) or upon expiration of a timer that was established by the system controller based on the system controller's estimate of how long the defrosting operation should be performed. In still another alternate embodiment, the system may otherwise detect completion of the defrosting operation.

If an exit condition has not occurred, then the defrosting operation may continue by iteratively performing blocks 622 and 624 (and the matching network reconfiguration process 610, as necessary). When an exit condition has occurred, then in block 628, the system controller causes the supply of the RF signal by the RF signal source to be discontinued. For example, the system controller may disable the RF signal generator (e.g., RF signal generator 342, FIG. 3) and/or may cause the power supply and bias circuitry (e.g., circuitry 350, FIG. 3) to discontinue provision of the supply current. In addition, the system controller may send signals to the user interface (e.g., user interface 320, FIG. 3) that cause the user interface to produce a user-perceptible indicia of the exit condition (e.g., by displaying “door open” or “done” on a display device, or providing an audible tone). The method may then end.

It should be understood that the order of operations associated with the blocks depicted in FIG. 6 corresponds to an example embodiment, and should not be construed to limit the sequence of operations only to the illustrated order. Instead, some operations may be performed in different orders, and/or some operations may be performed in parallel.

The connecting lines shown in the various figures contained herein are intended to represent exemplary functional relationships and/or physical couplings between the various elements. It should be noted that many alternative or additional functional relationships or physical connections may be present in an embodiment of the subject matter. In addition, certain terminology may also be used herein for the purpose of reference only, and thus are not intended to be limiting, and the terms “first”, “second” and other such numerical terms referring to structures do not imply a sequence or order unless clearly indicated by the context.

The foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with) another element, and not necessarily mechanically. Thus, although the schematic shown in the figures depict one exemplary arrangement of elements, additional intervening elements, devices, features, or components may be present in an embodiment of the depicted subject matter.

In an example embodiment, a thermal increase system may include a containment structure, a first electrode, a radio frequency (RF) signal source, and a transmission path. The first electrode may be disposed within the containment structure. The containment structure and the first electrode may define a first cavity in the containment structure on a first side of the first electrode and a second cavity in the containment structure on a second side of the first electrode. The first cavity may be configured to receive a first load and the second cavity is configured to receive a second load. The RF signal source may be configured to supply an RF signal to the first electrode. The transmission path may be electrically coupled between an output of the RF signal source and the first electrode. The RF signal may have a forward signal power along the transmission path.

In some embodiments, the thermal increase system may include a variable impedance matching network, power detection circuitry, and a controller. The variable impedance matching network may be electrically coupled along the transmission path between the RF signal source and the first electrode. The power detection circuitry may be configured to detect a reflected signal power along the transmission path. The controller may be configured to modify the variable impedance matching network to reduce a ratio of the reflected signal power to the forward signal power.

In some embodiments, the thermal increase system may include a second electrode and a third electrode. The second electrode may be capacitively coupled to the first electrode. The first cavity may be disposed between the first electrode and the second electrode. The third electrode may be capacitively coupled to the first electrode. The second cavity may be disposed between the first electrode and the third electrode.

In some embodiments, the containment structure may include a top wall and a bottom wall that opposes the top wall. The second electrode may form at least a portion of the top wall. The third electrode may form at least a portion of the bottom wall.

In some embodiments, the thermal increase system may include a first electrically insulative material layer and a second electrically insulative material layer. The first electrically insulative material layer may be disposed over and in direct contact with the first electrode. The second electrically insulative material layer may be disposed over and in direct contact with the bottom wall of the containment structure.

In some embodiments, when the RF signal source supplies the RF signal to the first electrode, a first magnitude of a first electric field between the first electrode and the second electrode is increased, and a second magnitude of a second electric field between the first electrode and the third electrode is increased.

In some embodiments, a first distance between the first electrode and the second electrode is in a range of 5 centimeters (cm) to 30 cm, and a second distance between the first electrode and the third electrode is in a range of 5 cm to 30 cm.

In some embodiments, a first value representing the first distance between the first electrode and the second electrode is within one percent of a second value representing the second distance between the first electrode and the third electrode.

In an example embodiment, a thermal increase system may include an RF signal source, a first electrode, a containment structure, a transmission path, power detection circuitry, and a controller. The RF signal source may be configured to supply an RF signal. The first electrode may receive the RF signal from the RF signal source. The containment structure may be capacitively coupled to the first electrode. The containment structure and the first electrode may define a first cavity in the containment structure on a first side of the first electrode and define a second cavity in the containment structure on a second side of the first electrode. The first cavity may be configured to receive a first load and the second cavity may be configured to receive a second load. The transmission path may be electrically coupled between an output of the RF signal source and the first electrode. The RF signal may have a forward signal power along the transmission path. The power detection circuitry may be configured to detect a reflected signal power along the transmission path. The controller may be configured to reduce a ratio of the reflected signal power to the forward signal power.

In some embodiments, the thermal increase system may be disposed within an appliance that is configured to maintain a constant temperature within the first cavity and the second cavity during normal operation of the appliance. The RF signal may be supplied to the first electrode during a thermal increase operation of the appliance. The first electrode may be disposed within a shelf of the appliance.

In some embodiments, the thermal increase system may include a second electrode and a third electrode. The second electrode may be capacitively coupled to the first electrode. The first cavity may be disposed between the first electrode and the second electrode. The third electrode may be capacitively coupled to the first electrode. The second cavity may be disposed between the first electrode and the third electrode.

In some embodiments, the containment structure may include a top wall and a bottom wall that is disposed opposite to the top wall. The second electrode may form at least a portion of the top wall. The third electrode may form at least a portion of the bottom wall.

In some embodiments, the thermal increase system may include a first electrically insulative barrier and a second electrically insulative barrier. The first electrically insulative barrier may be disposed over and in direct contact with the first electrode. The second electrically insulative barrier may be disposed over and in direct contact with the bottom wall of the containment structure.

In some embodiments, the second electrode and the third electrode may be electrically grounded via a ground reference terminal.

In an example embodiment, the thermal increase system may include a containment structure, a first electrode, and an RF signal source. The containment structure may include a plurality of walls. The first electrode may be disposed in the containment structure that divides the containment structure. The first electrode and the plurality of walls of the containment structure may define a first cavity that is configured to receive a first load and a second cavity that is configured to receive a second load. The first cavity and the second cavity may be separated by the first electrode. The RF signal source may be coupled to the first electrode via a transmission path and may be configured to supply an RF signal to the first electrode via the transmission path.

In some embodiments, the thermal increase may include power detection circuitry, a variable impedance matching network, and a controller. The power detection circuitry may be configured to detect a reflected signal power along the transmission path. The variable impedance matching network may be coupled along the transmission path. The controller may be configured to reduce the reflected signal power by modifying a state of the variable impedance matching network when the RF signal is supplied to the first electrode by the RF signal source.

In some embodiments, the plurality of walls may include a top wall and a bottom wall. The top wall may include a second electrode that is capacitively coupled to the first electrode. The bottom wall may include a third electrode that is capacitively coupled to the first electrode.

In some embodiments, when the RF signal is supplied to the first electrode, a first magnitude of a first electric field between the first electrode and the second electrode is increased, and a second magnitude of a second electric field between the first electrode and the third electrode is increased.

In some embodiments, a first height of the first cavity is within one percent of a second height of the second cavity.

In some embodiments, the thermal increase system may include a first non-electrically conductive barrier and a second non-electrically conductive barrier. The first non-electrically conductive barrier disposed on an upper surface of the first electrode. The second non-electrically conductive barrier may be disposed on an upper surface of the bottom wall.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A thermal increase system comprising:
a containment structure;
a first electrode disposed within the containment structure, wherein the containment structure and the first electrode define a first cavity in the containment structure on a first side of the first electrode and a second cavity in the containment structure on a second side of the first electrode, and the first cavity is configured to receive a first load and the second cavity is configured to receive a second load;
a radio frequency (RF) signal source configured to supply an RF signal to the first electrode; and
a transmission path electrically coupled between an output of the RF signal source and the first electrode, wherein the RF signal has a forward signal power along the transmission path.

2. The thermal increase system of claim 1, further comprising:
a variable impedance matching network electrically coupled along the transmission path between the RF signal source and the first electrode;
power detection circuitry configured to detect a reflected signal power along the transmission path; and
a controller configured to modify the variable impedance matching network to reduce a ratio of the reflected signal power to the forward signal power.

3. The thermal increase system of claim 1, further comprising:
a second electrode that is capacitively coupled to the first electrode, wherein the first cavity is disposed between the first electrode and the second electrode; and
a third electrode that is capacitively coupled to the first electrode, wherein the second cavity is disposed between the first electrode and the third electrode.

4. The thermal increase system of claim 3, wherein the containment structure comprises a top wall and a bottom wall that opposes the top wall, wherein the second electrode forms at least a portion of the top wall, and wherein the third electrode forms at least a portion of the bottom wall.

5. The thermal increase system of claim 4, further comprising:
a first electrically insulative material layer disposed over and in direct contact with the first electrode; and
a second electrically insulative material layer disposed over and in direct contact with the bottom wall of the containment structure.

6. The thermal increase system of claim 4, wherein, when the RF signal source supplies the RF signal to the first electrode, a first magnitude of a first electric field between the first electrode and the second electrode is increased, and a second magnitude of a second electric field between the first electrode and the third electrode is increased.

7. The thermal increase system of claim 3, wherein a first distance between the first electrode and the second electrode is in a range of 5 centimeters (cm) to 30 cm, and a second distance between the first electrode and the third electrode is in a range of 5 cm to 30 cm.

8. The thermal increase system of claim 7, wherein a first value representing the first distance between the first electrode and the second electrode is within one percent of a second value representing the second distance between the first electrode and the third electrode.

9. A thermal increase system comprising:
a radio frequency (RF) signal source configured to supply an RF signal;
a first electrode that receives the RF signal from the RF signal source;
a containment structure that is capacitively coupled to the first electrode, wherein the containment structure and the first electrode define a first cavity in the containment structure on a first side of the first electrode and define a second cavity in the containment structure on a second side of the first electrode, wherein the first cavity is configured to receive a first load and wherein the second cavity is configured to receive a second load;
a transmission path electrically coupled between an output of the RF signal source and the first electrode, wherein the RF signal has a forward signal power along the transmission path;
power detection circuitry configured to detect a reflected signal power along the transmission path; and
a controller configured to reduce a ratio of the reflected signal power to the forward signal power.

10. The thermal increase system of claim 9, wherein the thermal increase system is disposed within an appliance that is configured to maintain a constant temperature within the first cavity and the second cavity during normal operation of the appliance, wherein the RF signal is supplied to the first electrode during a thermal increase operation of the appliance, and wherein the first electrode is disposed within a shelf of the appliance.

11. The thermal increase system of claim 9, further comprising:
a second electrode that is capacitively coupled to the first electrode, wherein the first cavity is disposed between the first electrode and the second electrode; and
a third electrode that is capacitively coupled to the first electrode, wherein the second cavity is disposed between the first electrode and the third electrode.

12. The thermal increase system of claim 11, wherein the containment structure includes a top wall and a bottom wall that is disposed opposite to the top wall, wherein the second electrode forms at least a portion of the top wall, and wherein the third electrode forms at least a portion of the bottom wall.

13. The thermal increase system of claim 12, further comprising:
a first electrically insulative barrier disposed over and in direct contact with the first electrode; and
a second electrically insulative barrier disposed over and in direct contact with the bottom wall of the containment structure.

14. The thermal increase system of claim 12, wherein the second electrode and the third electrode are electrically grounded via a ground reference terminal.

15. A thermal increase system comprising:
a containment structure comprising a plurality of walls;
a first electrode disposed in the containment structure that divides the containment structure, wherein the first electrode and the plurality of walls of the containment structure define a first cavity that is configured to receive a first load and a second cavity that is configured to receive a second load, wherein the first cavity and the second cavity are separated by the first electrode; and
a radio frequency (RF) signal source that is coupled to the first electrode via a transmission path and that is configured to supply an RF signal to the first electrode via the transmission path.

16. The thermal increase system of claim 15, further comprising:
power detection circuitry configured to detect a reflected signal power along the transmission path;
a variable impedance matching network coupled along the transmission path; and
a controller configured to reduce the reflected signal power by modifying a state of the variable impedance matching network when the RF signal is supplied to the first electrode by the RF signal source.

17. The thermal increase system of claim 15, wherein the plurality of walls comprises:
a top wall that comprises a second electrode that is capacitively coupled to the first electrode; and
a bottom wall that comprises a third electrode that is capacitively coupled to the first electrode.

18. The thermal increase system of claim 17, wherein, when the RF signal is supplied to the first electrode, a first magnitude of a first electric field between the first electrode and the second electrode is increased, and a second magnitude of a second electric field between the first electrode and the third electrode is increased.

19. The thermal increase system of claim 17, wherein a first height of the first cavity is within one percent of a second height of the second cavity.

20. The thermal increase system of claim 17, further comprising:
a first non-electrically conductive barrier disposed on an upper surface of the first electrode; and
a second non-electrically conductive barrier disposed on an upper surface of the bottom wall.
